(19) United States
(12) Patent Application Publication
(10) Pub. No.: US 2020/0091845 A1
(43) Pub. Date: Mar. 19, 2020

(54) ROTOR POSITION ESTIMATION DEVICE, MOTOR CONTROL DEVICE, AND RECORDING MEDIUM

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Tamotsu ITO, Yokohama Kanagawa (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 16/290,894

(22) Filed: Mar. 2, 2019

(30) Foreign Application Priority Data
Sep. 19, 2018 (JP) 2018-175239

(51) Int. Cl. H02P 6/182; H02P 27/08; G01R 19/175; G01R 19/10; H03K 5/24

(52) U.S. Cl. CPC H02P 6/182; H02P 27/085; H03K 5/24; G01R 19/10; G01R 19/175

(57) ABSTRACT

A rotor position can be more reliably estimated and control can be performed even in a case where a rotation speed of a motor is increased by PWM control with a simple configuration.

A rotor position estimation device according to an embodiment is a rotor position estimation device used for a motor drive circuit that drives a three-phase alternating current motor by an inverter, and which estimates a rotational position of a rotor of the three-phase alternating current motor, the rotor position estimation device including a current difference detection circuit that detects a difference in current between first detection timing and second detection timing in at least one phase of three phases of the three-phase alternating current motor, a detection timing generation circuit that generates the first detection timing and the second detection timing such that a current flowing in a first direction by application of a power supply voltage and a current flowing in a second direction by application of the power supply voltage can be canceled in the phase to be detected in the current difference detection circuit, and a position estimation circuit that estimates the rotational position of the rotor on the basis of a zero crossing point of the difference in current.

### CROSS-REFERENCE TO RELATED APPLICATIONS

This application claims the benefit of priority from Japanese Application No. 2018-175239, filed on Sep. 19, 2018, the entire contents of which are incorporated herein by reference.

### FIELD

Embodiments described herein relate generally to a rotor position estimation device, a motor control device, and a recording medium.

### BACKGROUND

Conventionally, when rotation control of a three-phase brushless motor is performed by an inverter, a point (zero crossing point) at which a polarity of an induced voltage generated in each of U-phase, V-phase, and W-phase changes is detected to detect a rotor position, and PWM control is performed.

In this case, since the current zero crossing point where a change amount of the current flowing through each phase is zero can be approximated as a zero crossing point of the induced voltage, the current zero crossing point is detected in a state (zero vector) where a phase current does not flow in all three phases, and the rotor position is estimated.

[Patent Document 1] Japanese Patent Application Laid-Open No. 2008-029081

[Patent Document 2] Japanese Patent No. 6069024

[Patent Document 3] Japanese Patent Application Laid-Open No. 2007-236062

However, in the conventional technology, in a case of increasing a conducting duty by PWM control in order to increase a rotation speed of a motor, a period of the state (zero vector) in which the phase current does not flow in all three phases becomes short and a current change amount that is a differential value of a current amount becomes small, capture of the change becomes difficult, and accurate control may not be able to be performed.

The embodiments have been made in view of the foregoing, and an object of the embodiments is to provide a rotor position estimation device, a motor control device, and a recording medium for enabling more reliable estimation of a rotor position and control even in a case where rotation speed of a motor is increased by PWM control with a simple configuration.

A rotor position estimation device according to an embodiment is a rotor position estimation device used for a motor drive circuit that drives a three-phase alternating current motor by an inverter, and which estimates a rotational position of a rotor of the three-phase alternating current motor, the rotor position estimation device including a current difference detection circuit that detects a difference in current between first detection timing and second detection timing in at least one phase of three phases of the three-phase alternating current motor, a detection timing generation circuit that generates the first detection timing and the second detection timing such that a current flowing in a first direction by application of a power supply voltage and a current flowing in a second direction by application of the power supply voltage can be canceled in the phase for which the difference in current is to be detected, and a position estimation circuit that estimates the rotational position of the rotor on the basis of a zero crossing point of the difference in current.

### BRIEF DESCRIPTION OF THE DRAWINGS

FIG. 1 is a schematic block diagram of a motor drive circuit according to an embodiment;

FIG. 2 is an explanatory diagram of equivalent circuits of an inverter and a motor;

FIG. 3 is a diagram for describing a phase relationship between a rotor magnetic field and an induced voltage;

FIG. 4 is a diagram of an equivalent circuit for one phase of any of phases in FIG. 2;

FIG. 5 is an explanatory diagram of an example of conduction pattern to the motor;

FIG. 6 is an explanatory diagram of a closed loop between lines;

FIG. 7 is an explanatory diagram of motor resistance;

FIG. 8 is an explanatory diagram of a voltage at a neutral point;

FIGS. 9A and 9B are explanatory diagrams of one-phase equivalent circuits in an even vector V3 and an odd vector V1;

FIG. 10 is a schematic block diagram of a first mode of a more specific motor drive circuit;

FIG. 11 is an explanatory diagram of a first operation example;

FIG. 12 is an explanatory diagram of a second operation example;

FIG. 13 is an explanatory diagram of a third operation example;

FIG. 14 is an explanatory diagram of a fourth operation example;

FIG. 15 is a schematic block diagram of a second mode of the motor drive circuit;

FIG. 16 is a schematic block diagram of a third mode of the motor drive circuit; and

FIG. 17 is a schematic block diagram of a fourth mode of the motor drive circuit.

### DETAILED DESCRIPTION

Exemplary embodiments will be described below in detail with reference to the accompanying drawings.

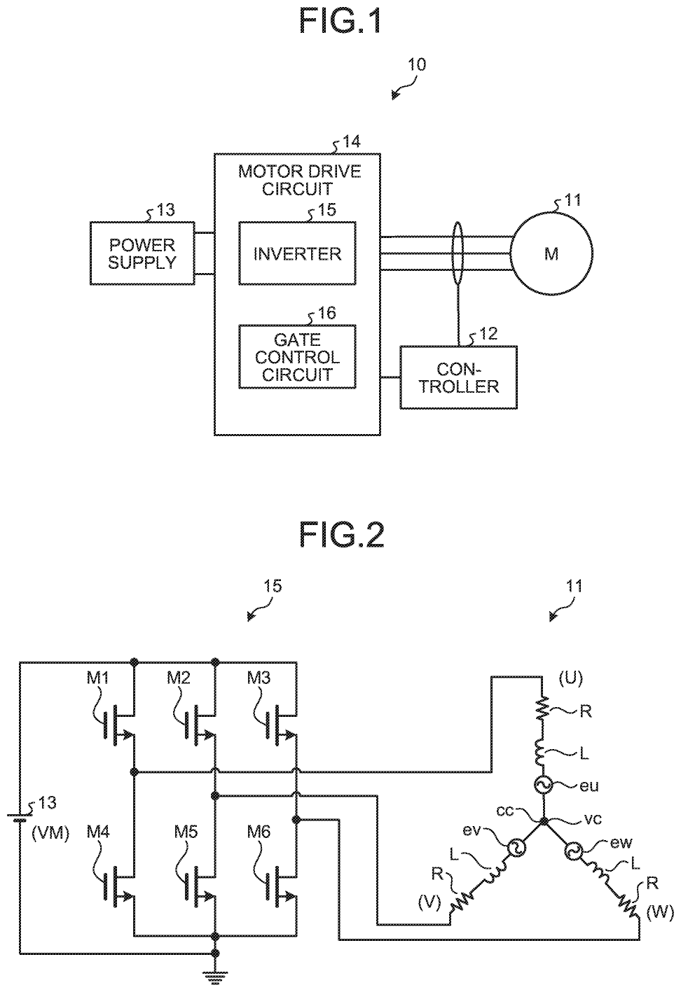

FIG. 1 is a schematic block diagram of a motor drive circuit according to an embodiment.

A motor drive circuit 10 includes a controller 12 that detects a drive state of a motor 11 and performs motor drive control, and a motor drive circuit 14 that receives power supply from a power source (direct current power supply) 13 and drives the motor 11 under the control of the controller 12.

The motor drive circuit 14 includes a gate control circuit 16 that performs gate control under the control of the controller 12, and an inverter 15 that is controlled by the gate control circuit 16, converts supplied direct current power into alternating current power, and supplies the alternating current power to the motor 11.

FIG. 2 is an explanatory diagram of equivalent circuits of an inverter and a motor.

The motor 11 has a configuration in which resistances R and inductors (coils) L corresponding to respective phases are connected at a neutral point CC (voltage Vc).

Here, induced voltages (back electromotive force: bemf) generated in a U-phase, a V-phase, and W-phase, respectively, are eu, ev, and ew.

In the case where a point at which the polarity of the induced voltages eu, ev, or ew changes is set as a zero crossing position, a rotor position of the motor 11 can be estimated by detecting the zero crossing position of the induced voltage.

Further, the inverter 15 includes NMOS transistors M1 and M4 corresponding to the U-phase, NMOS transistors M2 and M5 corresponding to the V-phase, and NMOS transistors M3 and M6 corresponding to the W-phase.

Further, the voltage of the power supply 13 is VM.

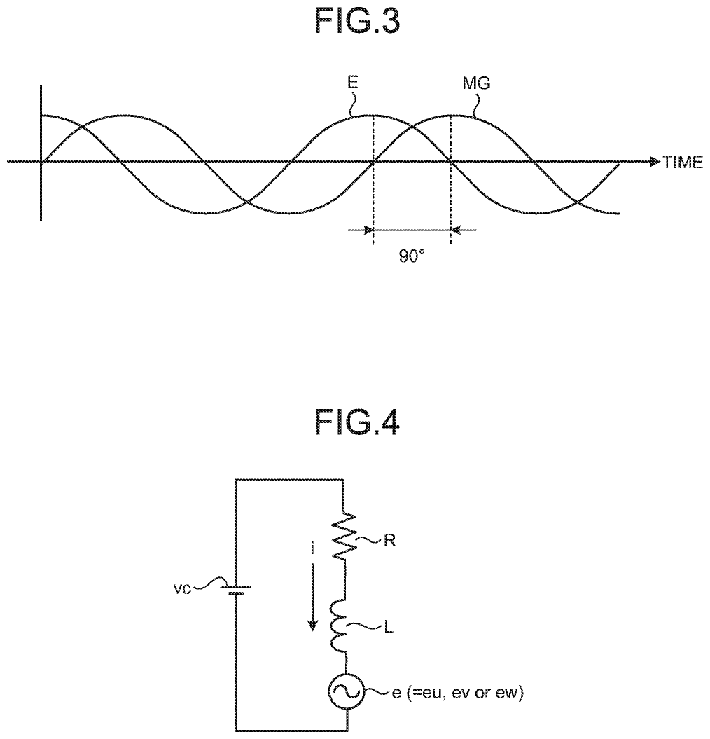

FIG. 3 is a diagram for describing a phase relationship between a rotor magnetic field and an induced voltage.

Since change in a magnetic field MG appears as an induced voltage E, phases of the magnetic field MG and the induced voltage E are shifted by 90 degrees. Therefore, when the zero crossing position of the induced voltage E is detected, a vertex position of the magnetic field of the rotor can be detected and the position of the rotor can be estimated.

FIG. 4 is a diagram of an equivalent circuit for one phase of any of phases in FIG. 2.

The voltage for one phase of the motor 11 in the case illustrated in FIG. 4 is expressed by Equation 1.

vc−e=R·i+L·di/dt (1)

Here, vc is the voltage of neutral point CC, e is one of induced voltages eu, ev, and ew generated in the U-phase, V-phase, and W-phase, R is resistance, L is inductance, i is a current, and di/dt is a differential value of the current.

Therefore, detection of the zero crossing position of the induced voltage e enables estimation of the position (phase) of the rotor.

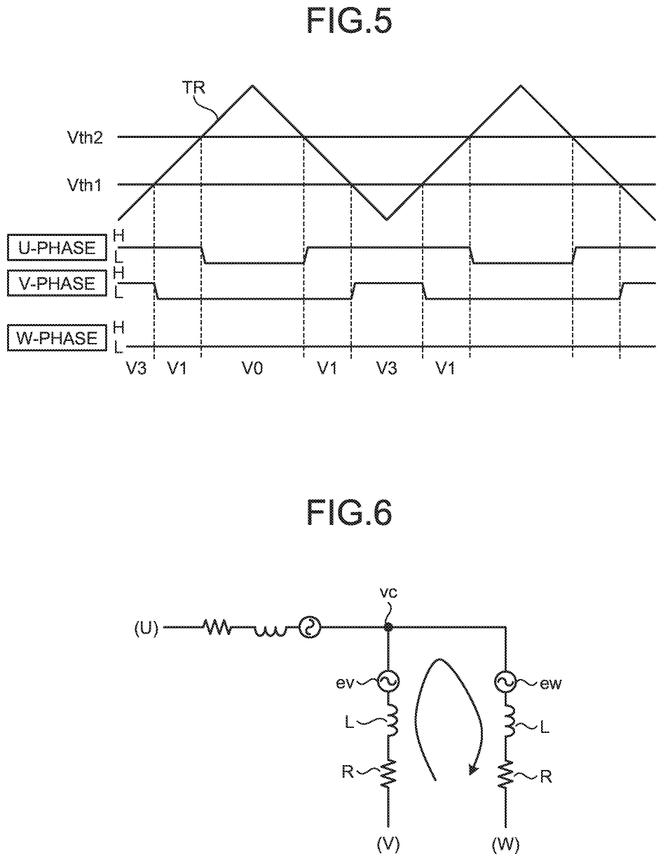

FIG. 5 is an explanatory diagram of an example of conduction pattern to the motor.

In FIG. 5, a triangular wave TR is a carrier in the case of generating a PWM control signal by a triangular wave comparison method, and a configuration of comparing comparative voltages Vth1 and Vth2 with a voltage of the triangular wave TR and outputting the PWM control signal is adopted.

In the following description, a state in which outputs of two phases are at an “H” level and an output of the other one phase is at an “L” level (hereinafter the state is referred to as even vector) is V3, a state in which an output of one phase is at the “H” level and outputs of the other two phases are at the “L” level (hereinafter the state is referred to as odd vector) is V1, and a state in which outputs of all the three phases are at the “L” level (hereinafter the state is referred to as zero vector) is V0.

In the one-phase motor voltage equation illustrated in Equation 1,

vc=0 (2)

is established in the case of the zero vector V0.

Further, in the case where the current i is around zero, Equation 3 is established.

R·i<<L·di/dt (3)

As a result, Equation 4 is established from Equation 1.

−e=L·di/dt (4)

As described above, di/dt is the differential value of the current=change in the current, and the zero crossing point of di/dt can be approximated to the zero crossing point of induced voltage, so the position of the rotor can be estimated from the zero crossing point of the induced voltage.

However, to increase the rotation of the motor 11, a conducting duty needs to be increased, and the time of the zero vector V0 becomes inevitably short.

As a result, a current change amount per unit time represented by di/dt also becomes small, and capture of the change becomes difficult.

On the other hand, the time of the odd vector V1 and the even vector V3 becomes longer as the conducting duty is increased.

In the odd vector V1, the transistors M1, M2, and M6 in FIG. 2 are in an open state (off state) and the transistors M3, M4, and M5 are in a close state (on state), for example.

FIG. 6 is an explanatory diagram of a closed loop between lines.

Considering the closed loop between lines of the V-phase and the W-phase in FIG. 6 in the state of the odd vector V1, for example, the voltage between the two lines of the V-phase and W-phase with the outputs at the “L” level is expressed by Equation 5.

0−(ev−ew)=R(iv−iw)+L·(div/dt−diw/dt) (5)

Here, assume that Equation 6 is established in the vicinity of the zero crossing of the current (iv−iw) as in Equation 3.

R(iv−iw)<<L(div/dt−diw/dt) (6)

As a result, Equation 5 can be approximated as Equation 7.

(ev−ew)=L(div/dt−diw/dt) (7)

That is, the zero crossing point of the induced voltage between lines can be detected from the zero crossing point of a current change difference between the two lines (V-phase-W-phase in the above example).

Assuming that the induced voltage between two lines is called inter-line induced voltage, it is well known that a phase voltage and the inter-line induced voltage are shifted by 30 degrees, so estimation of the position of the rotor from the inter-line induced voltage is theoretically possible.

However, to obtain the current change difference in the above processing, current comparison needs to be performed a plurality of times within the odd vector V1 or a plurality of times in a period of the successive odd vector V1->zero vector V0->odd vector V1.

That is, in any of the methods, a sequence of the even vector V3 cannot be included during a measurement period that is a period from the start of the current measurement to the end of a plurality of times of the current measurement to obtain one current change difference, and the measurement period is limited.

In addition, there is a problem that the inter-line induced voltage is smaller than the phase voltage and the detection accuracy is inferior.

Therefore, the present embodiment proposes a detection method using the phase voltage, and capable of detecting the rotor position even in the case where the sequences of the zero vector V0, the odd vector V1, and the even vector V3 are mixed, and lengthening the measurement period to increase the current change amount (=di/dt), thereby improving the detection accuracy.

First, the voltage Vc at the neutral point of the motor 11 is obtained.

Discussing the U-phase, the relationship between a voltage Vu of the U-phase and the voltage Vc can be expressed by Equation (8).

Vu−Vc=Ru·Iu+eu+Lu·diu/dt (8)

Here, Ru is the resistance of the U-phase, Iu is a U-phase current, eu is a U-phase back electromotive force, Lu is U-phase inductance, and diu/dt is a change amount of the U-phase current.

When transforming Equation 8, the U-phase current Iu is expressed by Equation 9.

Iu=(Vu−Vc−eu−Lu·diu/dt)/Ru (9)

Similarly, a V-phase current Iv is expressed by Equation 10, and a W-phase current Iw is expressed by Equation 11.

Iv=(Vv−Vc−ev−Lv·div/dt)/Rv (10)

Iw=(Vw−Vc−ew−Lw·diw/dt)/Rw (11)

Note that the pieces of resistance in the respective phases satisfy Ru=Rv=Rw (=R) and the pieces of inductance in the respective phases satisfy Lu=Lv=Lw (=L).

Further, a composite current of the three phases can be expressed by Equation 12.

Iu+Iv+Iw=0 (12)

Similarly, di/dt is the differential amount of each current, and the sum of the change amounts of the three phases is zero, so Equation 13 is established.

diu/dt+div/dt+diw/dt=0 (13)

Further, since the induced voltages eu, ev, and ew are sinusoidal waves that are different in phase by 120 degrees from one another and a composite voltage of the three phases is zero, the composite voltage of the three phases is expressed by Equation 14.

eu+ev+ew=0 (14)

As a result, Equation 15 is established.

Vc=(Vu+Vv+Vw)/3 (15)

That is, according to Equation 15, the voltage Vc becomes a fixed value depending on each state of the zero vector V0, the odd vector V1, and the even vector V3 regardless of the rotor phase or conduction state.

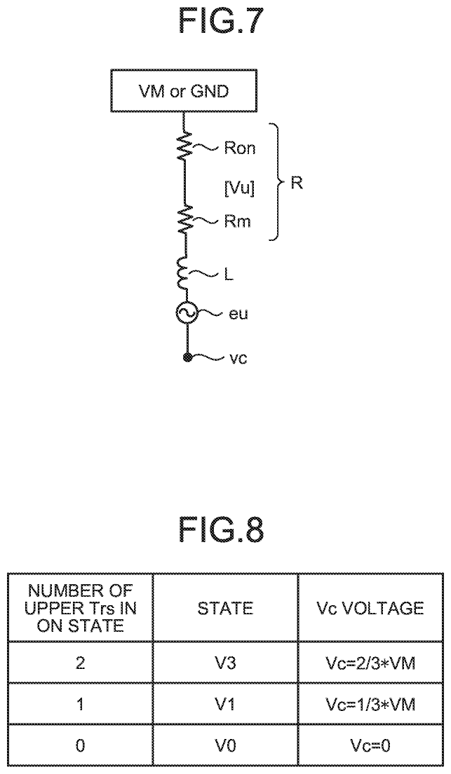

FIG. 7 is an explanatory diagram of motor resistance.

Here, assuming that pieces of on-resistance Ron of the transistors M1 to M6 corresponding to the U-phase, the V-phase, and the W-phase constituting the inverter are the same, the resistance in each phase in FIG. 7 is Ron+Rm (Rm is wire resistance).

In this case, the U-phase voltage Vu is equal to a voltage VM (Vu=VM) in a case where the transistor M1 is in an on state, and Vu=0 in a case where the transistor M1 is in an off state.

Similarly, the V-phase voltage Vv satisfies Vv=VM in a case where the transistor M2 is in an on state, and Vv=0 in a case where the transistor M2 is in an off state. The W-phase voltage Vw satisfies Vw=VM in a case where the transistor M3 is in an on state, and Vu=0 in a case where the transistor M3 is in an off state.

FIG. 8 is an explanatory diagram of a voltage Vc at a neutral point.

In a case where the upper three transistors M1 to M3 in FIG. 8 are in an on state, the voltage Vc becomes a fixed value, satisfying the voltage Vc=VM, from Equation 15.

Further, in a case where two of the transistors M1 to M3 are in an on state, the voltage Vc becomes a fixed value, satisfying the voltage Vc=(⅔)*VM, from Equation 15.

Further, in a case where one of the transistors M1 to M3 is in an on state, the voltage Vc becomes a fixed value, satisfying the voltage Vc=(⅓)*VM, from Equation 15.

Further, in a case where the three transistors M1 to M3 are in an off state, the voltage Vc becomes a fixed value, satisfying the voltage Vc=0, from Equation 15.

Hereinafter, specific description will be given.

(1) Case of Even Vector V3

In the case of the even vector V3, the outputs of two phases are at the “H” level and the output of one phase is at the “L” level.

For example, assume that the transistors M1, M2, and M6 are in an on state and the transistors M3, M4, and M5 are in an off state. That is, the U-phase and V-phase output voltages are VM and the W-phase output voltage is GND (=0).

(2) Case of Odd Vector V1

In the case of the odd vector V1, the output of one phase is at the “H” level and the outputs of two phases are at the “L” level.

For example, assume that transistors M1, M5, and M6 are in an on state and transistors M2, M3, and M4 are in an off state. That is, the U-phase output voltage is VM and the V-phase and W-phase output voltages are GND.

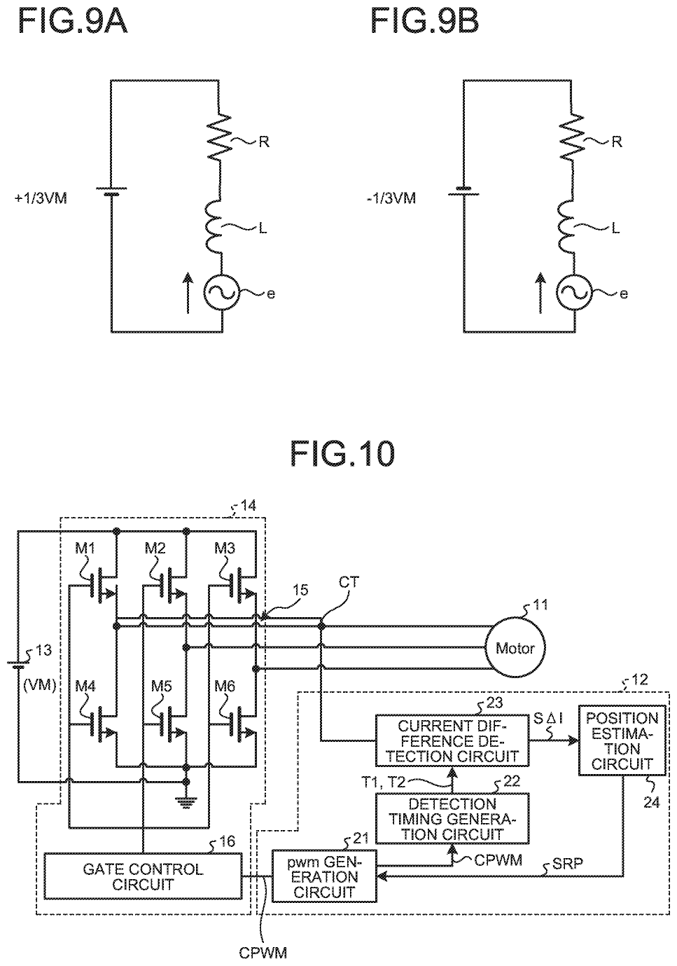

FIGS. 9A and 9B are explanatory diagrams of one-phase equivalent circuits in “H” level and “L” level outputs.

In the case of the even vector V3 or the odd vector V1, at least one phase is at the “H” level or the “L” level.

At the “H” level, the equivalent circuit become the state as illustrated in FIG. 9A, and the voltage Vc at the neutral point=(⅔)·VM, so a difference between a power supply voltage VM and the voltage Vc is expressed by the following equation.

VM−Vc=VM−(⅔)VM=(⅓)VM

Further, at the “L” level, the equivalent circuit become the state as illustrated in FIG. 9B, and the voltage Vc at the neutral point=(⅓)·VM, so a difference between a ground voltage GND and the voltage Vc is expressed by the following equation.

0−Vc=0−(⅓)·VM=−(⅓)·VM

(3) Case of Zero Vector V0

In the case of the zero vector V0, the outputs of all the three phases are at the “L” level.

That is, the transistors M1 to M3 are all in an off state and the transistors M4 to M6 are all in an on state. The U-phase, V-phase, and W-phase output voltages are all the ground voltage GND.

In the case of the zero vector V0, the voltage Vc at the neutral point is 0, and the difference between the ground voltage GND and the voltage Vc does not occur.

As described above, the voltages applied between lines in the case of transitioning from the even vector V3 to the odd vector V1 are +(⅓)·VM and −(⅓)·VM. Here, a general equation of transient analysis of an RL circuit illustrated in FIGS. 9A and 9B is Equation 16.

ΔI=e/R·(1−exp(−R·tx/L)) (16)

Here, tx is target time of the transient analysis.

Here, a current change amount ΔI obtained by combining the current flowing at the voltage=(⅓)·VM and the current flowing at the induced voltage e can be obtained by the superposition theorem.

Further, a current change amount ΔI1 of the current flowing at the voltage ⅓VM is expressed by Equation 17.

ΔI1=((⅓)VM/R)(1−exp(−R·t1/L))+((−⅓)VM/R)(1−exp(−R·t2/L)) (17)

Further, a current change amount ΔI2 of the current flowing at the induced voltage e can be expressed by Equation 18.

ΔI2=−e/R·(1−exp(−R·t1/L))+(−e/R)*(1−exp(−R·t2/L)) (18)

In Equations 18 and 19, t1 is the period (time) of the even vector V3 during measurement and t2 is the period (time) of the odd vector V1 during measurement.

Further, a composite current change amount ΔI of the current flowing at the voltage=(⅓)·VM and the current flowing at the induced voltage e is expressed by Equation 19.

ΔI=ΔI1+ΔI2 (19)

Here, assume that control is performed to equalize the period t1 of the even vector V3 and the period t2 of the odd vector V1. That is,

t1=t2=t.

As a result, ΔI1=0 is obtained, which becomes equivalent to performing measurement at timing when the currents flowing through the motor 11 are canceled, so the rotor position can be easily estimated.

Further, ΔI2=−2e·(1−exp(−R·t/L)). Therefore, Equation 19 becomes Equation 20.

ΔI=−2e(1−exp(−R·t/L)) (20)

In Equation 20, the time t can be arbitrarily set within a range satisfying a measurement condition, and the resistance R and the inductance L are constants peculiar to the motor 11.

Therefore, according to the present embodiment, the current change amount ΔI depends only on the induced voltage e (=eu, ev, or ew) and is equivalent to performing measurement at the timing when the currents flowing through the motor 11 are canceled. By detecting the zero crossing of the current, the zero crossing point of the induced voltage e can be detected and the zero crossing position can be easily estimated.

FIG. 10 is a schematic block diagram of a first mode of a more specific motor drive circuit.

In FIG. 10, similar parts to parts in FIG. 1 are denoted by the same reference numerals.

The controller 12 in FIG. 10 includes a PWM generation circuit 21, a detection timing generation circuit 22, a current difference detection circuit 23, and a position estimation circuit 24.

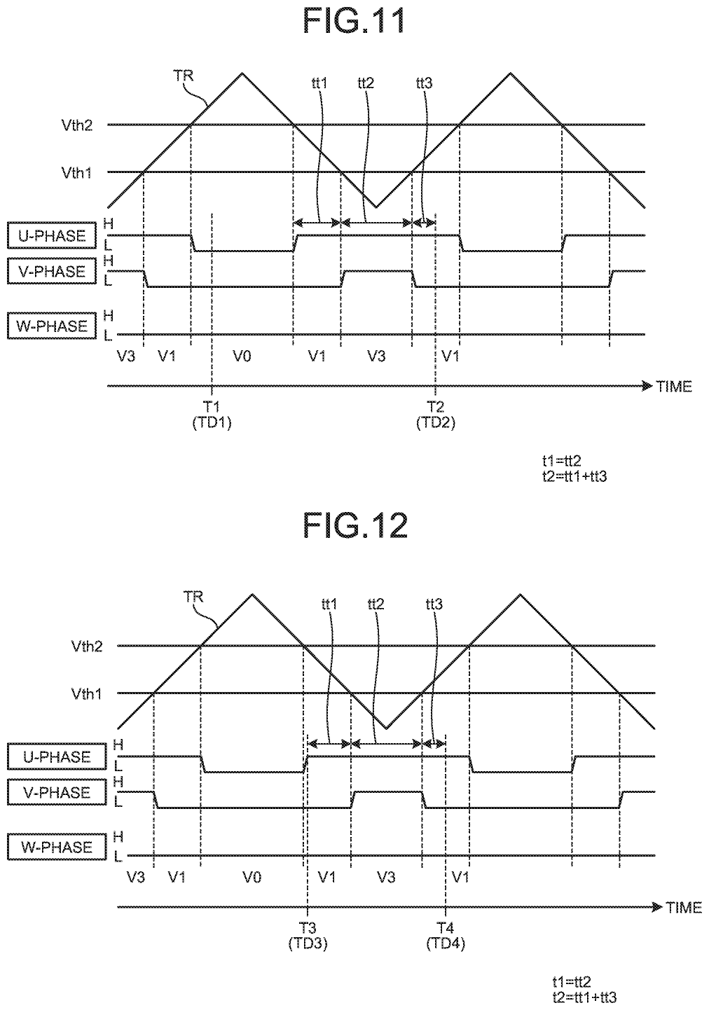

FIG. 11 is an explanatory diagram of a first operation example.

The PWM generation circuit 21 generates a PWM control signal CPWM on the basis of a rotor position estimation signal SRP (an initial value is a predetermined value), and outputs the PWM control signal CPWM to the gate control circuit 16 and the detection timing generation circuit 22.

As a result, the detection timing generation circuit 22 appropriately generates detection timing T1 on the basis of the PWM control signal CPWM and generates detection timing T2 such that the period t1 of the even vector V3 and the period t2 of the odd vector V1 become equal on or after the detection timing T1, and outputs the detection timing T1 and T2 to the current difference detection circuit 23.

Specifically, the detection timing generation circuit 22 performs control to cause the current difference detection circuit 23 to detect the current, setting time TD1 as the detection timing T1, during the period of the zero vector V0.

Further, the detection timing generation circuit 22 performs control to cause the current difference detection circuit 23 to detect the current, setting time TD2 as the detection timing T2, such that the period t2 of the odd vector V1 and the period t1 of the even vector V3 become equal, during a measurement period. In FIG. 11, the detection timing generation circuit 22 performs control such that the period of the odd vector V1 becomes tt1+tt3, the period of the even vector V3 becomes tt2, and tt1+tt3=tt2.

As a result, the current difference detection circuit 23 detects currents at timing based on the detection timing T1 and T2 by a current detection sensor CT, respectively, detects a current difference between a current value at the time T1 and a current value at the time T2, and outputs a current difference signal SΔI corresponding to the current difference to the position estimation circuit 24.

The position estimation circuit 24 estimates the rotor position on the basis of the current difference corresponding to the current difference signal SΔI, and outputs the rotor position estimation signal SRP to the PWM generation circuit 21.

Therefore, after the above process, the PWM generation circuit 21 generates the PWM control signal CPWM on the basis of the estimated rotor position, controls the inverter 15 via the gate control circuit 16, and controls the motor 11 on the basis of the rotor position.

According to the first operation example, the zero crossing point of the induced voltage e can be detected at the timing when the current change amount ΔI depends only on the induced voltage e (=eu, ev, or ew), and furthermore, the zero crossing point of the rotor magnetic field can be easily estimated, and the rotor position can be more reliably estimated.

FIG. 12 is an explanatory diagram of a second operation example.

In the first operation example of FIG. 11, the time TD1 during the period of the zero vector V0 has been set as the detection timing T1. The second operation example is different from the first operation example in setting time TD3 during a period of the odd vector V1.

The PWM generation circuit 21 generates a PWM control signal CPWM on the basis of a rotor position estimation signal SRP (an initial value is a predetermined value), and outputs the PWM control signal CPWM to the gate control circuit 16 and the detection timing generation circuit 22.

As a result, the detection timing generation circuit 22 generates detection timing T3 and T4 such that the period t1 of the even vector V3 and the period t2 of the odd vector V1 become equal on the basis of the PWM control signal CPWM, and outputs the detection timing T3 and T4 to the current difference detection circuit 23.

Specifically, the detection timing generation circuit 22 performs control to cause the current difference detection circuit 23 to detect the current, setting time TD3 as the detection timing T3, during the period of the odd vector V1.

Further, the detection timing generation circuit 22 performs control to cause the current difference detection circuit 23 to detect the current, setting time TD4 as the detection timing T4, such that the period t2 of the odd vector V1 and the period t1 of the even vector V3 become equal, during a measurement period.

As a result, the current difference detection circuit 23 detects a difference in the current value between the time TD3 and the time TD4, and outputs a current difference signal SΔI to the position estimation circuit 24.

The position estimation circuit 24 estimates the rotor position on the basis of the current difference corresponding to the current difference signal SΔI, and outputs the rotor position estimation signal SRP to the PWM generation circuit 21.

Therefore, after the above process, the PWM generation circuit 21 generates the PWM control signal CPWM on the basis of the estimated rotor position, controls the inverter 15 via the gate control circuit 16, and controls the motor 11 on the basis of the rotor position.

According to the second operation example, the zero crossing point of the induced voltage e can be detected at the timing when the current change amount ΔI depends only on the induced voltage e (=eu, ev, or ew), and furthermore, the zero crossing point of the rotor magnetic field can be easily estimated, and the rotor position can be more reliably estimated.

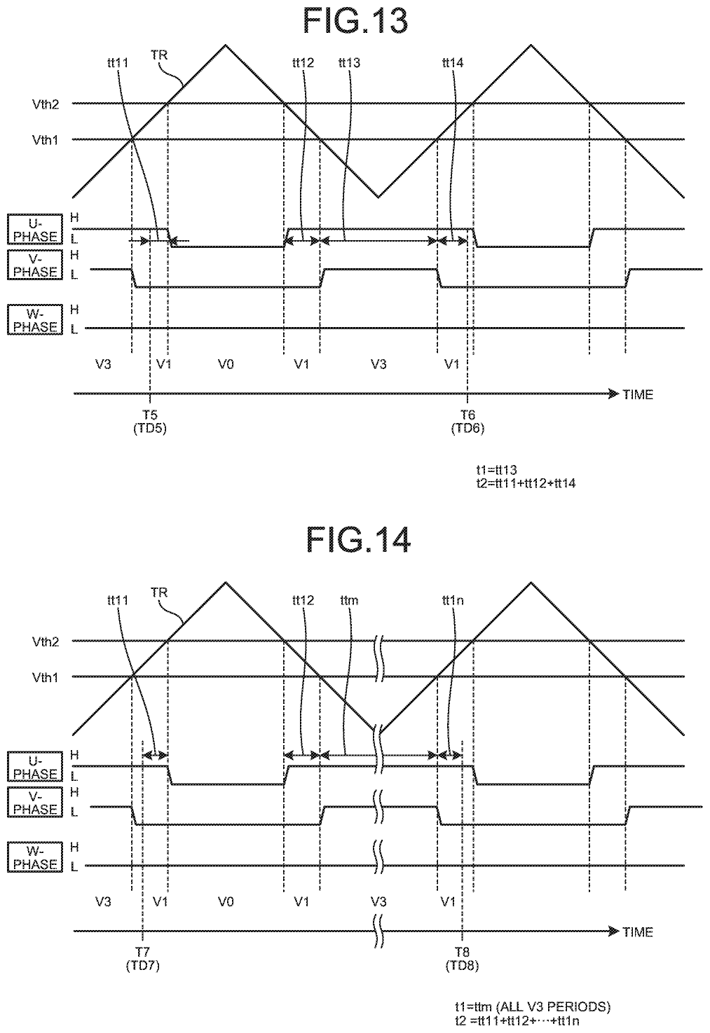

FIG. 13 is an explanatory diagram of a third operation example.

In the first operation example in FIG. 11 and the second operation example in FIG. 12, the detection timing T1 and T2 or the detection timing T3 and T4 has been set in the same sequence (the successive odd vector V1 and even vector V3). The third operation example is different from the first and second operation examples in setting detection timing T5 and detection timing T6 in different sequences.

In this case, variation of the PWM control signals CPWM needs to fall within a range in which the PWM control signals CPWM are identical or regarded as identical under the control of the motor 11 in a period defined by the detection timing T5 and the detection timing T6.

The PWM generation circuit 21 generates the PWM control signal CPWM on the basis of a rotor position estimation signal SRP (an initial value is a predetermined value), and outputs the PWM control signal CPWM to the gate control circuit 16 and the detection timing generation circuit 22.

As a result, the detection timing generation circuit 22 generates detection timing T5 and T6 such that the period t1 of the even vector V3 and the period t2 of the odd vector V1 become equal on the basis of the PWM control signal CPWM, and outputs the detection timing T5 and T6 to the current difference detection circuit 23.

Specifically, the detection timing generation circuit 22 performs control to cause the current difference detection circuit 23 to detect the current, setting time TD5 as the detection timing T5, during the period of the odd vector V1.

Further, the detection timing generation circuit 22 performs control to cause the current difference detection circuit 23 to detect the current, setting time TD6 as the detection timing T6, such that the period t2 of the odd vector V1 and the period t1 of the even vector V3 become equal, during a measurement period. In FIG. 13, the detection timing generation circuit 22 performs control such that the period of the odd vector V1 becomes tt13, the period of the even vector V3 becomes tt11+tt12+tt14, and tt13=tt11+tt12+tt14.

As a result, the current difference detection circuit 23 detects a difference in the current value between the time TD5 and the time TD6, and outputs a current difference signal SΔI to the position estimation circuit 24.

The position estimation circuit 24 estimates the rotor position on the basis of the current difference corresponding to the current difference signal SΔI, and outputs the rotor position estimation signal SRP to the PWM generation circuit 21.

Therefore, after the above process, the PWM generation circuit 21 generates the PWM control signal CPWM on the basis of the estimated rotor position, controls the inverter 15 via the gate control circuit 16, and controls the motor 11 on the basis of the rotor position.

According to the third operation example, the zero crossing point of the induced voltage e can be detected at the timing when the current change amount ΔI depends only on the induced voltage e (=eu, ev, or ew), and furthermore, the zero crossing point of the rotor magnetic field can be easily estimated, and the rotor position can be more reliably estimated.

FIG. 14 is an explanatory diagram of a fourth operation example.

In the third operation example in FIG. 13, the detection timing T5 and the detection timing T6 have been set in the two successive sequences. The fourth operation example is different from the third operation example in setting detection timing T7 and detection timing T8 in three or more successive sequences.

In this case, variation of the PWM control signals CPWM needs to fall within a range in which the PMW control signals CPWM are identical or regarded as identical under the control of the motor 11 in a period defined by the detection timing T7 and the detection timing T8.

The PWM generation circuit 21 generates a PWM control signal CPWM on the basis of a rotor position estimation signal SRP (an initial value is a predetermined value), and outputs the PWM control signal CPWM to the gate control circuit 16 and the detection timing generation circuit 22.

As a result, the detection timing generation circuit 22 generates detection timing T7 and T8 such that the period t1 of the even vector V3 and the period t2 of the odd vector V1 become equal on the basis of the PWM control signal CPWM, and outputs the detection timing T7 and T8 to the current difference detection circuit 23.

Specifically, the detection timing generation circuit 22 performs control to cause the current difference detection circuit 23 to detect the current, setting time TD7 as the detection timing T7, during the period of the odd vector V1.

Further, the detection timing generation circuit 22 performs control to cause the current difference detection circuit 23 to detect the current, setting time TD8 as the detection timing T8, such that the period of the odd vector V1 and all the periods of the even vector V3 become equal, during a measurement period. In FIG. 14, the detection timing generation circuit 22 performs control such that the period of the odd vector V1 becomes tt11+tt12+ . . . +tt1n, the period of the even vector V3 becomes ttm, and tt11+tt12+ . . . +tt1n=ttm.

As a result, the current difference detection circuit 23 detects a difference in the current value between the time TD7 and the time TD8, and outputs a current difference signal SΔI to the position estimation circuit 24.

The position estimation circuit 24 estimates the rotor position on the basis of the current difference corresponding to the current difference signal SΔI, and outputs the rotor position estimation signal SRP to the PWM generation circuit 21.

Therefore, after the above process, the PWM generation circuit 21 generates the PWM control signal CPWM on the basis of the estimated rotor position, controls the inverter 15 via the gate control circuit 16, and controls the motor 11 on the basis of the rotor position.

According to the fourth operation example, the zero crossing point of the induced voltage e can be detected at the timing when the current change amount ΔI depends only on the induced voltage e (=eu, ev, or ew), and furthermore, the zero crossing point of the rotor magnetic field can be easily estimated, and the rotor position can be more reliably estimated.

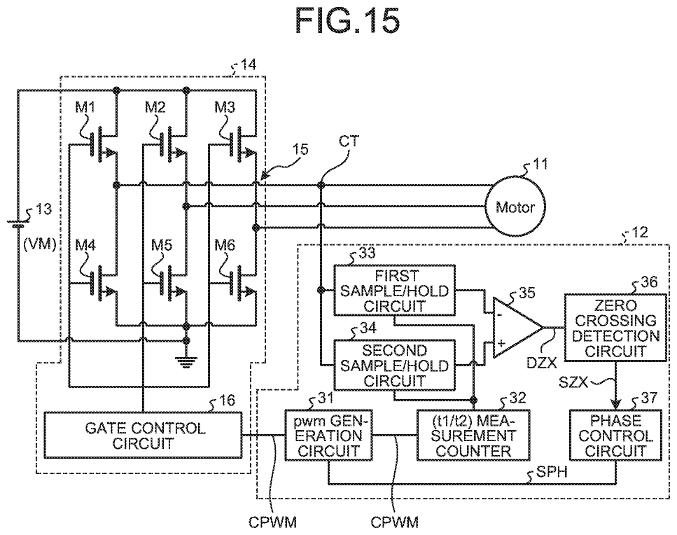

FIG. 15 is a schematic block diagram of a second mode of a more specific motor drive circuit.

In FIG. 15, similar parts to parts in FIG. 1 are denoted by the same reference numerals, and description will be given with reference to FIG. 11.

The controller 12 in FIG. 15 includes a PWM generation circuit 31, a measurement counter 32, a first sample/hold circuit 33, a second sample/hold circuit 34, a zero crossing comparator 35, a zero crossing detection circuit 36, and a phase control circuit 37.

The PWM generation circuit 31 generates a PWM control signal CPWM on the basis of a phase control signal SPH (an initial value is a predetermined value), and outputs the PWM control signal CPWM to the gate control circuit 16 and the measurement counter 32.

As a result, the measurement counter 32 appropriately generates detection timing T1 on the basis of the PWM control signal CPWM and generates detection timing T2 such that the period t1 of the even vector V3 and the period t2 of the odd vector V1 become equal within a period from the detection timing T1 to the detection timing T2, and outputs the detection timing T1 and T2 to the first sample/hold circuit 33 and the second sample/hold circuit 34.

More specifically, the measurement counter 32 individually counts the period t1 of the even vector V3 and the period t2 of the odd vector V1 determined on the basis of the PWM control signal CPWM with a clock signal generated by the measurement counter 32 from the generated detection timing T1 or an input clock signal, generates detection timing T2 at timing when the period t1 of the even vector V3 and the period t2 of the odd vector V1 become equal (or timing regarded as equal), and outputs the detection timing T1 and the detection timing T2 to the first sample/hold circuit 33 and the second sample/hold circuit 34.

Specifically, the measurement counter 32 outputs time TD1 to the first sample/hold circuit 33 as the detection timing T1 during the period of the zero vector V0.

Further, the measurement counter 32 outputs time TD2 as the detection timing T2 to the second sample/hold circuit 34 such that the period t2 of the odd vector V1 and the period t1 of the even vector V3 become equal during a measurement period.

As a result, the first sample/hold circuit 33 samples, detects, and holds a current by the current detection sensor CT on the basis of the detection timing T1, and the second sample/hold circuit 34 samples, detects, and holds a current by the current detection sensor CT on the basis of the detection timing T1.

Then, the zero crossing comparator 35 compares an output of the first sample/hold circuit 33 input to an inverting input terminal with an output of the second sample/hold circuit 34 input to a non-inverting input terminal, and outputs zero crossing detection data DZX to the zero crossing detection circuit 36.

The zero crossing detection circuit 36 outputs a zero crossing detection signal SZX to the phase control circuit 37 on the basis of the zero crossing detection data.

The phase control circuit 37 outputs a phase control signal SPH for controlling the phase of the PWM control signal CPWM to the PWM generation circuit 31 on the basis of the zero crossing detection signal SZX.

Therefore, after the above process, the PWM generation circuit 31 generates the PWM control signal CPWM on the basis of the phase control signal SPH, controls the inverter 15 via the gate control circuit 16, and controls the motor 11 on the basis of the rotor position.

According to the operation example, the zero crossing point of the induced voltage e can be detected at the timing when the current change amount ΔI depends only on the induced voltage e (=eu, ev, or ew), and furthermore, the zero crossing point of the rotor magnetic field can be easily estimated, and the rotor position can be more reliably estimated.

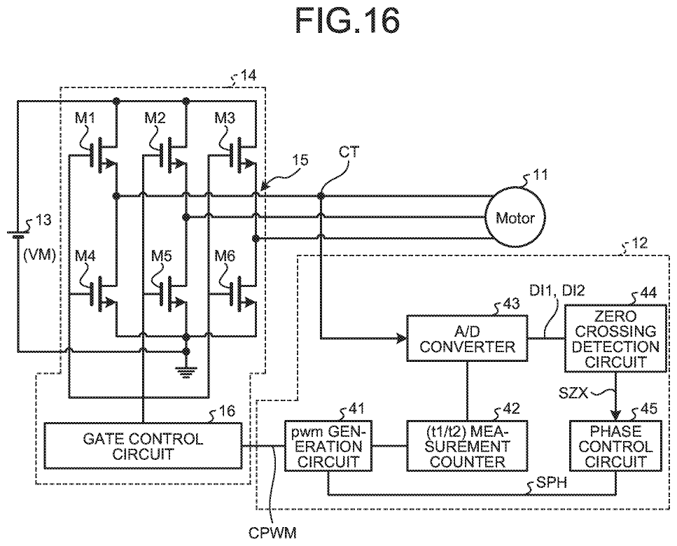

FIG. 16 is a schematic block diagram of a third mode of a more specific motor drive circuit:

In FIG. 16, similar parts to parts in FIG. 1 are denoted by the same reference numerals, and description will be given with reference to FIG. 11.

The controller 12 in FIG. 16 includes a PWM generation circuit 41, a measurement counter 42, an A/D converter 43, a zero crossing detection circuit 44, and a phase control circuit 45.

The PWM generation circuit 41 generates a PWM control signal CPWM on the basis of a phase control signal SPH (an initial value is a predetermined value), and outputs the PWM control signal CPWM to the gate control circuit 16 and the measurement counter 32.

As a result, the measurement counter 42 counts and generates detection timing T1 and T2 such that the period t1 of the even vector V3 and the period t2 of the odd vector V1 become equal on the basis of the PWM control signal CPWM, and outputs the detection timing T1 and T2 to the A/D converter 43.

Specifically, the measurement counter 42 outputs time TD1 to the A/D converter 43 as the detection timing T1 during the period of the zero vector V0.

Further, the measurement counter 42 outputs time TD2 as the detection timing T2 to the A/D converter 43 such that the period t2 of the odd vector V1 and the period t1 of the even vector V3 become equal during a measurement period.

As a result, the A/D converter 43 performs A/D conversion for current detection signals by the current detection sensor CT and outputs first current detection data DI1 and second current detection data DI2 to the zero crossing detection circuit 44 at the detection timing T1 and T2.

The zero crossing detection circuit 44 compares the first current detection data DI1 with the second current detection data DI2 at predetermined timing and outputs the zero crossing detection signal SZX to the position estimation circuit 45.

The position estimation circuit 45 outputs a phase control signal SPH for controlling the phase of the PWM control signal CPWM to the PWM generation circuit 41 on the basis of the zero crossing detection signal SZX.

Therefore, after the above process, the PWM generation circuit 41 generates the PWM control signal CPWM on the basis of the phase control signal SPH, controls the inverter 15 via the gate control circuit 16, and controls the motor 11 on the basis of the rotor position.

According to the operation example, the zero crossing point of the induced voltage e can be detected at the timing when the current change amount ΔI depends only on the induced voltage e (=eu, ev, or ew), and furthermore, the zero crossing point of the rotor magnetic field can be easily estimated, and the rotor position can be more reliably estimated.

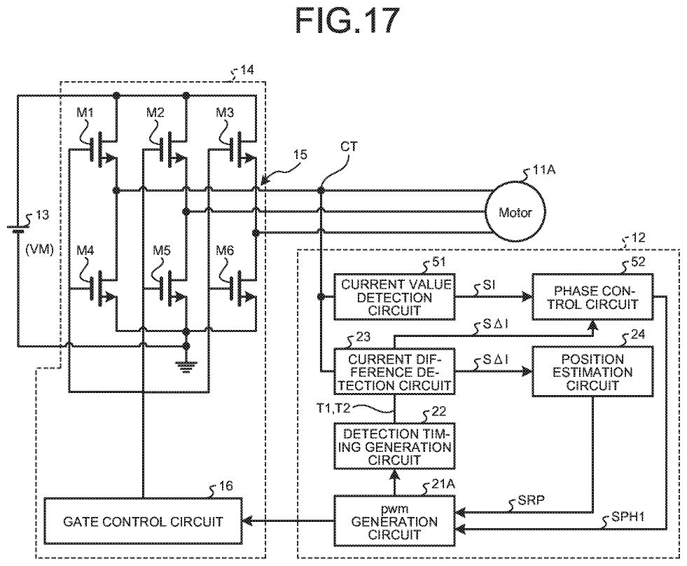

FIG. 17 is a schematic block diagram of a fourth mode of a more specific motor drive circuit.

In FIG. 17, similar parts to parts in FIG. 10 are denoted by the same reference numerals.

In FIG. 17, differences from the motor drive circuit in FIG. 10 are that a surface permanent magnet synchronous motor (SPMSM) 11A is used in place of the motor 11, and a current value detection circuit 51 that detects a current value by the current detection sensor CT at predetermined timing and outputs a current detection signal SI, and a phase control circuit 52 that generates and outputs a phase control signal SPH1 on the basis of the current detection signal SI and a current difference signal SΔI output by the current difference detection circuit 23 are included.

According to the above configuration, a PWM generation circuit 21A performs control to match phases at a zero crossing position of a current flowing in each phase of a motor 11A and a zero crossing position of an induced voltage on the basis of the rotor position estimation signal SRP and the phase control signal SPH1 output by the position estimation circuit 24, thereby further enhancing the efficiency of the motor 11A.

Further, the PWM generation circuit 21A makes the zero crossing position of the current flowing in each phase of the motor 11A earlier than the zero crossing position of the induced voltage on the basis of the rotor position estimation signal SRP and the phase control signal SPH1, thereby increasing the rotation speed of the motor 11A.

The controller 12 of the motor drive circuit 10 according to the present embodiment is configured as a microcomputer including an MPU, and a program to be executed by the controller 12 is incorporated in advance in a ROM or the like and provided.

Alternatively, the program executed by the controller 12 may be provided after being recorded on a computer-readable non-transitory recording medium such as a USB memory, a semiconductor device such as a memory card, a CD-ROM, or a digital versatile disk (DVD) in an installable or executable format file.

Furthermore, the program executed by the controller 12 may be stored on a computer connected to a network such as the Internet and provided by being downloaded via the network. Further, the program executed by the controller 12 of the motor drive circuit 10 of the present embodiment may be provided or distributed via a network such as the Internet.

What is claimed is:

1. A rotor position estimation device used for a motor drive circuit that drives a three-phase alternating current motor by an inverter, and which estimates a rotational position of a rotor of the three-phase alternating current motor, the rotor position estimation device comprising:
a current difference detection circuit that detects a difference in current between first detection timing and second detection timing in at least one phase of three phases of the three-phase alternating current motor;
a detection timing generation circuit that generates the first detection timing and the second detection timing such that a current flowing in a first direction by application of a power supply voltage and a current flowing in a second direction by application of the power supply voltage can be canceled in the phase to be detected in the current difference detection circuit; and
a position estimation circuit that estimates the rotational position of the rotor on the basis of a zero crossing point of the difference in current.

2. The rotor position estimation device according to claim 1, wherein
the detection timing generation circuit generates the first detection timing and the second detection timing such that an even vector period in which outputs of any two phases of the three phases are at an “H level” and an output of one phase is at an “L level”, and an odd vector period in which an output of any one phase is at the “H level” and outputs of two phases are at the “L level” become equal, during a detection period from the first detection timing to the second detection timing.

3. The rotor position estimation device according to claim 1, wherein
the current difference detection circuit includes
a first sample/hold circuit that samples and holds a first current value at the first detection timing;
a second sample/hold circuit that samples and holds a second current value at the second detection timing;
a comparator that compares the first current value with the second current value; and
a zero crossing detection circuit that detects a zero crossing point of the difference in current on the basis of an output of the comparator.

4. The rotor position estimation device according to claim 1, wherein
the current difference detection circuit includes
an A/D converter that samples a current value at the first detection timing, performs A/D conversion, and outputs the current value as first current data, and samples a current value at the second detection timing, performs A/D conversion, and outputs the current value as second current data, and
a zero crossing detection circuit that detects a zero crossing point of the difference in current and outputs a zero crossing detection signal on the basis of the first current data and the second current data.

5. The rotor position estimation device according to claim 2, wherein
the detection timing generation circuit sets the first detection timing during a zero vector period in which outputs of the three phases are all at the “L level”.

6. The rotor position estimation device according to claim 2, wherein
the detection timing generation circuit sets the first detection timing during the odd vector period.

7. The rotor position estimation device according to claim 2, wherein
the detection timing generation circuit sets the first detection timing and the second detection timing such that a zero vector period in which one or a plurality of outputs of the three phases are all at the “L level” is included between the first detection timing and the second detection timing.

8. A motor control device comprising:
an inverter that drives a three-phase alternating current motor;
a current difference detection circuit that detects a difference in current between first detection timing and second detection timing in at least one phase of three phases of the three-phase alternating current motor;
a detection timing generation circuit that generates the first detection timing and the second detection timing such that a current flowing in a first direction by application of a power supply voltage and a current flowing in a second direction by application of the power supply voltage can be canceled in the phase to be detected in the current difference detection circuit;
a position estimation circuit that estimates the rotational position of the rotor on the basis of a zero crossing point of the difference in current; and
a PWM generation circuit that generates a signal for controlling the inverter on the basis of an estimation result of the rotational position of the rotor.

9. The motor control device according to claim 8, wherein
the detection timing generation circuit generates the first detection timing and the second detection timing such that an even vector period in which outputs of any two phases of the three phases are at an “H level” and an output of one phase is at an “L level”, and an odd vector period in which an output of any one phase is at the “H level” and outputs of two phases are at the “L level” become equal, during a detection period from the first detection timing to the second detection timing.

10. The motor control device according to claim 9, wherein
the detection timing generation circuit sets the first detection timing during a zero vector period in which outputs of the three phases are all at the “L level”.

11. The motor control device according to claim 9, wherein
the detection timing generation circuit sets the first detection timing during the odd vector period.

12. The motor control device according to claim 9, wherein
the detection timing generation circuit sets the first detection timing and the second detection timing such that a zero vector period in which one or a plurality of outputs of the three phases are all at the “L level” is included between the first detection timing and the second detection timing.

13. The motor control device according to claim 12, wherein
a period defined by the first detection timing and the second detection timing is set such that variation of the signals for controlling the inverter output from the PWM generation circuit falls within a range in which the signals are regarded as identical under control of the three-phase alternating current motor.

14. A non-transitory computer readable recording medium recording a program for causing a computer to control a rotor position estimation device used for a motor drive circuit that drives a three-phase alternating current motor by an inverter, and which estimates a rotational position of a rotor of the three-phase alternating current motor, the program for causing the computer to function as:
a unit that detects a difference in current between first detection timing and second detection timing in at least one phase of three phases of the three-phase alternating current motor;
a unit that generates the first detection timing and the second detection timing such that a current flowing in a first direction by application of a power supply voltage and a current flowing in a second direction by application of the power supply voltage can be canceled in the phase to be detected in the unit that detects a difference in current; and
a unit that estimates the rotational position of the rotor on the basis of a zero crossing point of the difference in current.
